(19) United States
(12) Patent Application Publication
(10) Pub. No.: US 2025/0169040 A1
(43) Pub. Date: May 22, 2025

(54) NEGATIVE PRESSURE COOLING DISTRIBUTION UNIT HEAT DISSIPATION SYSTEM

(71) Applicant: New H3C Technologies Co., Ltd., Hangzhou (CN)

(72) Inventors: Kuiyang WANG, Beijing (CN); Haichao LV, Beijing (CN); Guogang WU, Beijing (CN); Libo CHEN, Beijing (CN)

(73) Assignee: New H3C Technologies Co., Ltd., Hangzhou (CN)

(21) Appl. No.: 18/940,603

(22) Filed: Nov. 7, 2024

(30) Foreign Application Priority Data
Nov. 17, 2023 (CN) 202311544807.7

(51) Int. Cl. H05K 7/20

(52) U.S. Cl. CPC H05K 7/20281; H05K 7/20254; H05K 7/20263; H05K 7/20272

(57) ABSTRACT

In the present disclosure, a negative pressure cooling distribution unit (CDU) heat dissipation system comprises a cold plate assembly, a liquid pump, and a heat exchanger. A liquid outlet of the cold plate assembly is connected to a liquid inlet of the liquid pump, the liquid pump is to pressurize liquid flow from the liquid outlet of the cold plate assembly. A liquid outlet of the liquid pump is connected to a liquid inlet of the heat exchanger, the heat exchanger is to perform heat exchange, and a liquid outlet of the heat exchanger is connected to a liquid inlet of a pressure regulator; the pressure regulator is to adjust liquid pressure within a pipeline to below one atmosphere. A liquid outlet of the pressure regulator is connected to a liquid inlet of the cold plate assembly. The first pressure detector is to detect a first pressure at the liquid inlet of the cold plate assembly; and the first temperature detector is to detect a first temperature at the liquid inlet of the cold plate assembly; wherein the first temperature is regulated by the heat exchanger to be maintained at a set temperature value. The system in the examples of the present disclosure operates safely and reliably, with excellent fluid control responsiveness and simple structure and control logic.

### CROSS-REFERENCE TO RELATED APPLICATIONS

The present application claims priority to Chinese Patent Application No. 202311544807.7, filed Nov. 17, 2023, which is incorporated herein by reference in its entirety.

### TECHNICAL FIELD

The present disclosure relates to the field of communication technology, and particularly to a negative pressure Cooling Distribution Unit (CDU) heat dissipation system.

### BACKGROUND

With the rapid development of the server industry, the integration level of internal electronic assemblies, such as Central Processing Units (CPUs) and memories, has continued to increase, leading to a rapid rise in heat flux density. During operation, these electronic assemblies generate significant amounts of heat, which can adversely affect the normal functioning of the product if the heat cannot be promptly expelled from the system. As the heat generation of assemblies continues to escalate, existing air-cooling solutions have become inadequate to meet product demands. Liquid cooling, as an emerging and highly efficient cooling method, offers reliable and safe operation. The CDU, as the cold source assembly of liquid cooling, plays a pivotal role in the entire liquid cooling system. The use of a positive pressure CDU heat dissipation system poses a risk of fluid leakage leading to product downtime and damage, whereas the use of a negative pressure CDU heat dissipation system can avoid this issue. The CDU heat dissipation system is a heat dissipation solution employed in server rooms or data centers. The CDU heat dissipation system is responsible for transporting cooled liquid to the cold plates located near heat sources, thereby cooling the heat-generating assemblies. A negative pressure CDU refers to a system where the liquid pressure within the pipeline is maintained below one atmosphere during operation; in the event of a pipe leak, the internal fluid is prevented from leaking due to the pushback force of atmospheric pressure.

To the inventor's knowledge, existing negative pressure CDU system solutions exhibit suboptimal fluid control responsiveness, coupled with complex system structures and control logic.

### SUMMARY

This specification provides a negative pressure CDU cooling system to overcome the problems in related technologies.

In an example of this specification, the negative pressure CDU heat dissipation system comprises a cold plate assembly, a liquid pump, and a heat exchanger. The liquid outlet of the cold plate assembly is connected to the liquid inlet of the liquid pump, which pressurizes liquid flow from the liquid outlet of the cold plate assembly. The liquid outlet of the liquid pump is connected to the liquid inlet of the heat exchanger, and after heat exchange, the liquid outlet of the heat exchanger is connected to the liquid inlet of a pressure regulator. The pressure regulator adjusts the liquid pressure within the pipeline to below one atmosphere, and the liquid outlet of the pressure regulator is connected to the liquid inlet of the cold plate assembly. A first pressure and a first temperature at the liquid inlet of the cold plate assembly are detected by a first pressure detector and a first temperature detector. The first temperature is regulated by the heat exchanger to be maintained at a set value.

In some examples, a secondary protection device is installed between the liquid outlet of the pressure regulator and the liquid inlet of the cold plate assembly.

Moreover, the secondary protection device includes two flow path branches. The first branch includes a bypass valve disposed between the liquid outlet of the pressure regulator and the liquid inlet of the cold plate assembly. The second branch includes a stop valve and a pressure relief device, with the liquid outlet of the stop valve being connected to the liquid inlet of the pressure relief device. The second branch is connected in parallel with the first branch, with the liquid inlet of the stop valve being connected to the liquid inlet of the bypass valve and the liquid outlet of the stop valve being connected to the liquid outlet of the bypass valve.

In some examples, a second pressure detector is installed at the liquid outlet of the pressure regulator to detect a second pressure at the liquid outlet of the pressure regulator. With the second pressure being less than or equal to one atmosphere, the bypass valve of the first branch of the secondary protection device is opened, and the stop valve of the second branch is closed. Conversely, with the second pressure being greater than one atmosphere, the bypass valve of the first branch of the secondary protection device is closed, and the stop valve of the second branch is opened.

In some examples, the pressure regulator includes a regulating valve, a pressure reducing valve, a throttle valve, or an open-expansion liquid tank.

In some examples, a flow rate detector is installed at the liquid outlet of the cold plate assembly.

In some examples, a third pressure detector is installed at the liquid inlet of the liquid pump to detect a third pressure at the liquid inlet of the liquid pump.

In some examples, a second temperature detector is installed at the liquid inlet of the liquid pump to detect a second temperature at the liquid inlet of the liquid pump.

The technical solution provided by the examples of this specification can include the following beneficial effects:

The negative pressure CDU system in the examples of this specification detects the first pressure through the first pressure detector and regulates the first pressure to below one atmosphere using the pressure regulator. The system operates safely and reliably, with excellent fluid control responsiveness and simple structure and control logic.

It should be understood that the above general description and subsequent detailed descriptions are merely illustrative and explanatory in nature and do not limit the scope of this specification.

### BRIEF DESCRIPTION OF THE DRAWINGS

The schematic diagrams described here are provided to further understand the present disclosure and constitute a part of the present disclosure. The illustrative examples of the present disclosure and the description thereof are used to explain the present disclosure and do not constitute an improper limitation on the present disclosure.

FIG. 1 is a schematic diagram of the principle in an example of the present disclosure;

FIG. 2 is a schematic diagram of the principle in an example of the present disclosure;

FIG. 3 is a schematic diagram of the principle in an example of the present disclosure;

FIG. 4 is a schematic diagram of the principle in an example of the present disclosure.

### DETAILED DESCRIPTION

The exemplary examples will be described in detail herein, with examples illustrated in the accompanying drawings. When the following description refers to the drawings, unless otherwise indicated, the same numbers in different drawings represent the same or similar elements. The examples described in the following exemplary examples do not represent all examples consistent with this specification. Rather, they are merely examples of devices and methods consistent with some aspects of this specification, as detailed in the appended claims.

The terminology used in this specification is for the purpose of describing particular examples only and is not intended to be limiting. The singular forms “a,” “an,” and “the” used in this specification and the appended claims are intended to include the plural forms as well, unless the context clearly indicates otherwise. It should also be understood that the term “and/or” used herein refers to and encompasses any and all possible combinations of one or more of the associated listed items.

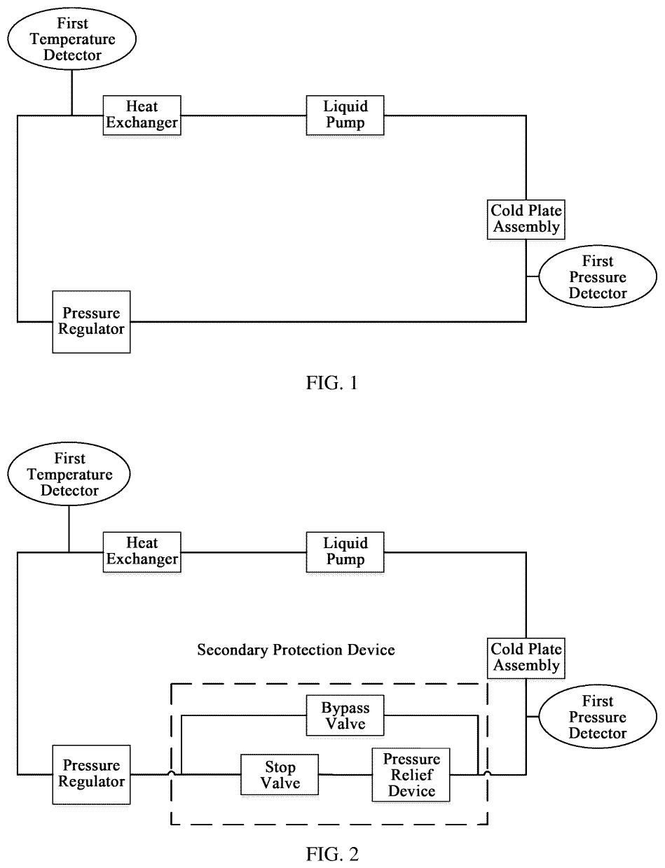

In an example of the present disclosure, a negative pressure CDU heat dissipation system, as shown in FIG. 1, at least comprises a cold plate assembly, a liquid pump, a heat exchanger, a pressure regulator, and pipelines connected thereto. The liquid outlet of the cold plate assembly is connected to the liquid inlet of the liquid pump, which pressurizes liquid flow from the liquid outlet of the cold plate assembly. The liquid outlet of the liquid pump is connected to the liquid inlet of the heat exchanger, and the liquid outlet of the heat exchanger, after heat exchange between hot and cold liquids, is connected to the liquid inlet of the pressure regulator. The pressure regulator adjusts the pressure of the liquid within the pipeline to maintain the pressure below one atmosphere. The liquid outlet of the pressure regulator is connected to the liquid inlet of the cold plate assembly, a closed loop is completed. The closed loop is: the cold plate assembly-the liquid pump-the heat exchanger-the pressure regulator-the cold plate assembly. The first pressure and the first temperature at the liquid inlet of the cold plate assembly are detected by the first pressure detector and a first temperature detector. In response to a determination that the first pressure detector detects that the first pressure at the liquid inlet of the cold plate assembly is greater than or equal to one atmosphere, the pressure regulator is controlled to adjust the pressure to ensure that the first pressure at the liquid inlet of the cold plate assembly is less than one atmosphere. The first temperature at the liquid inlet of the cold plate assembly is detected by the first temperature detector and maintained at a set value through the heat exchanger. The cold plate assembly includes a cold plate and a chip located below the cold plate, which achieves cooling and heat dissipation of the chip below through heat exchange and thermal conduction of the liquid within the cold plate. Therefore, the liquid entering the cold plate needs to be maintained at a relatively low temperature to effectively dissipate heat from the chip below. The first temperature is a preset temperature, which can be adjusted by the heat exchanger if the first temperature is too high. The heat exchanger can be a liquid-liquid heat exchanger, an air-liquid heat exchanger, etc. Taking an air-liquid heat exchanger as an example, adjusting the fan speed alters the first temperature. Similarly, in a liquid-liquid heat exchanger, altering the exchange rate between the primary cold fluid and the secondary hot fluid achieves temperature control. The example of the present disclosure operates safely and reliably, with good fluid control timeliness and simple structure and control logic. In the example of the present disclosure, the first temperature detector can be installed at any position on the pipeline after the heat exchanger and before the cold plate assembly. The pressure regulator in the example of the present disclosure can be a regulating valve, a pressure reducing valve, a throttle valve, or an open-expansion liquid tank. In the example of the present disclosure, the first pressure should be maintained below one atmosphere but not too low, with the negative pressure at the liquid inlet of the liquid pump being sufficient to avoid cavitation erosion.

Because issues such as pressure regulator damage may occur during the application of the system in this disclosure, leading to the inability of the pressure regulator to regulate pressure normally, on the basis of the above example, as shown in FIG. 2, this disclosure provides another preferred example, wherein the secondary protection device is installed between the liquid outlet of the pressure regulator and the liquid inlet of the cold plate assembly. Here, this disclosure presents an example of the secondary protection device, which includes two flow path branches. The first branch includes a bypass valve arranged between the liquid outlet of the pressure regulator and the liquid inlet of the cold plate assembly. The second branch includes a stop valve and a pressure relief device. The first branch and the second branch are connected in parallel, wherein the liquid inlet of the stop valve is connected to the liquid inlet of the bypass valve, the liquid outlet of the stop valve is connected to the liquid inlet of the pressure relief device, and the liquid outlet of the stop valve is connected to the liquid outlet of the bypass valve via the pressure relief device. In the example of this disclosure, if the first pressure detector detects that the first pressure is less than or equal to one atmosphere, the first branch is conducted, and the stop valve of the second branch is disconnected. If the first pressure detector detects that the first pressure is greater than one atmosphere, the first branch is disconnected, and the stop valve of the second branch is conducted, adjusting the first pressure to less than or equal to one atmosphere. The pressure relief device in this example may be a pressure relief valve, etc., which is provided herein as an example and does not constitute a limitation.

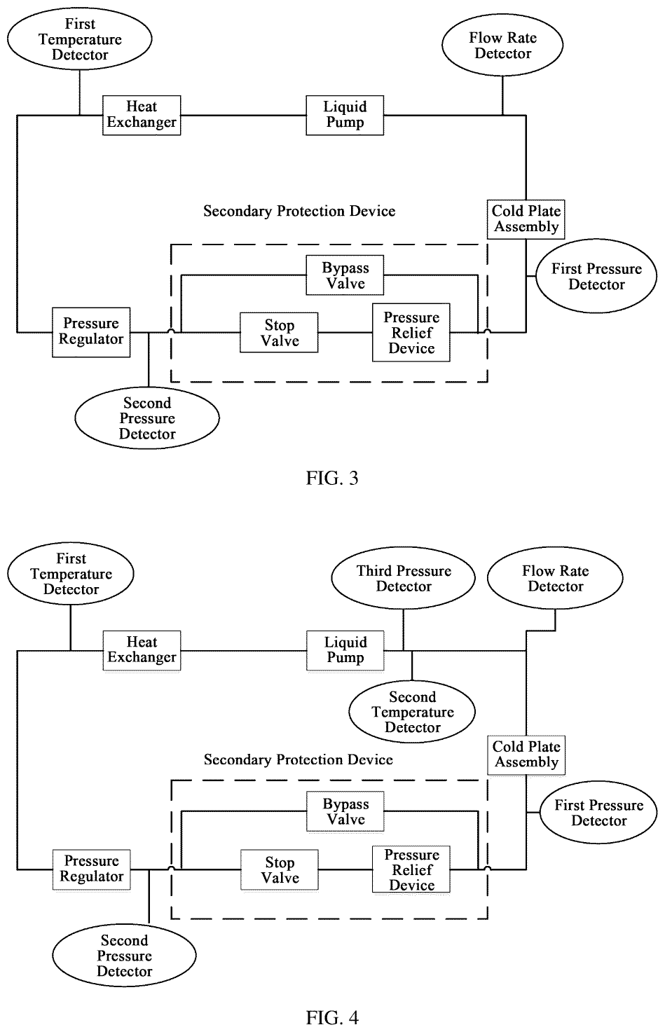

As another preferred example, as shown in FIG. 3, the second pressure detector is installed at the liquid outlet of the pressure regulator. The second pressure at the liquid outlet of the pressure regulator is detected by the second pressure detector. With the second pressure being less than or equal to one atmosphere, the bypass valve of the first branch of the secondary protection device is conducted, and the stop valve of the second branch is disconnected. With the second pressure being greater than one atmosphere, the bypass valve of the first branch of the secondary protection device is disconnected, and the stop valve of the second branch is conducted. By adding the second pressure detector, in response to determine that the detected pressure at the liquid outlet is greater than one atmosphere, the pressure at the liquid inlet of the cold plate assembly can be immediately reduced to below one atmosphere through the secondary protection device.

As shown in FIG. 3, the example of this disclosure further includes installing the flow rate detector at the liquid outlet of the cold plate assembly. The flow rate detector is used to detect the flow rate flowing into the liquid pump. The liquid pump performs real-time flow control within the system based on the detected flow rate to ensure that the flow rate within the system meets the target requirements. Furthermore, an initial system adjustment data can be provided initially, and an analysis data of the current flow rate can be provided during system troubleshooting for reference.

As shown in FIG. 4, in another example of this disclosure, the third pressure detector is installed at the liquid inlet of the liquid pump to detect the third pressure at the liquid inlet of the liquid pump, monitoring flow resistance through the third pressure.

As shown in FIG. 4, in another example of this disclosure, a second temperature detector is installed at the liquid inlet of the liquid pump to detect the second temperature at the liquid inlet of the liquid pump. The second temperature at the liquid inlet of the liquid pump is equal to the temperature at the liquid outlet of the cold plate assembly. The temperature at the liquid outlet of the cold plate assembly is monitored in real-time to ensure that the temperature does not change significantly.

The liquid in the system pipeline of this disclosure can be water, fluorinated liquid, etc.

Specific examples of this specification have been described above. Other examples fall within the scope of the appended claims. In some cases, the actions or steps recorded in the claims can be executed in an order different from that in the examples and still achieve the desired results. Furthermore, the processes depicted in the drawings do not necessarily require the specific order or continuous sequence shown to achieve the desired results. In certain examples, multitasking and parallel processing are also possible or may be advantageous.

Those skilled in the art will readily conceive of other examples of this specification after considering the specification and practicing the invention disclosed herein. This specification is intended to cover any variations, uses, or adaptations of this specification that follow the general principles of this specification and include common knowledge or conventional technical means in the art that are not claimed in this specification. The specification and examples are merely exemplary, and the true scope and spirit of this specification are indicated by the following claims.

It should be understood that this specification is not limited to the precise structures described above and shown in the drawings, and various modifications and changes can be made without departing from its scope. The scope of this specification is limited only by the appended claims.

The above examples are only preferred examples of this specification and are not intended to limit this specification. Any modifications, equivalent replacements, improvements, etc. made within the spirit and principles of this specification should be included within the scope of protection of this specification.

What is claimed is:

1. A negative pressure cooling distribution unit (CDU) heat dissipation system comprising a cold plate assembly, a liquid pump, and a heat exchanger, wherein the system further comprises a first pressure detector and a first temperature detector;
a liquid outlet of the cold plate assembly is connected to a liquid inlet of the liquid pump; the liquid pump is to pressurize liquid flow from the liquid outlet of the cold plate assembly;
a liquid outlet of the liquid pump is connected to a liquid inlet of the heat exchanger; the heat exchanger is to perform heat exchange;
a liquid outlet of the heat exchanger is connected to a liquid inlet of a pressure regulator; the pressure regulator is to adjust liquid pressure within a pipeline to below one atmosphere,
a liquid outlet of the pressure regulator is connected to a liquid inlet of the cold plate assembly;
the first pressure detector is to detect a first pressure at the liquid inlet of the cold plate assembly; and
the first temperature detector is to detect a first temperature at the liquid inlet of the cold plate assembly; wherein the first temperature is regulated by the heat exchanger to be maintained at a set temperature value.

2. The system of claim 1, wherein
a secondary protection device is provided between the liquid outlet of the pressure regulator and the liquid inlet of the cold plate assembly.

3. The system of claim 2, wherein
the secondary protection device comprises two flow path branches including a first branch and a second branch arranged parallel to the first branch;
the first branch comprises a bypass valve disposed between the liquid outlet of the pressure regulator and the liquid inlet of the cold plate assembly; and the second branch comprises a stop valve and a pressure relief device, a liquid outlet of the stop valve is connected to a liquid inlet of the pressure relief device;
a liquid inlet of the stop valve is connected to a liquid inlet of the bypass valve, and the liquid outlet of the stop valve is connected to a liquid outlet of the bypass valve via the pressure relief device.

4. The system of claim 3, wherein the system further comprises a second pressure detector;
the second pressure detector is provided at the liquid outlet of the pressure regulator and is to detect a second pressure at the liquid outlet of the pressure regulator; wherein
the secondary protection device is to:
open the bypass valve of the first branch and close the stop valve of the second branch while the second pressure is less than or equal to one atmosphere; and
close the bypass valve of the first branch and open the stop valve of the second branch while the second pressure is greater than one atmosphere.

5. The system of claim 4, wherein
the pressure regulator comprises a regulating valve, a pressure reducing valve, a throttle valve, or an open-expansion liquid tank.

6. The system of claim 4, wherein
a flow rate detector is provided at the liquid outlet of the cold plate assembly.

7. The system of claim 5, wherein
a third pressure detector is provided at the liquid inlet of the liquid pump and is to detect a third pressure at the liquid inlet of the liquid pump.

8. The system of claim 6, wherein
a second temperature detector is provided at the liquid inlet of the liquid pump and is to detect a second temperature at the liquid inlet of the liquid pump.
